(19) United States
(12) Patent Application Publication
(10) Pub. No.: US 2026/0344076 A1
(43) Pub. Date: Oct. 29, 2026

(54) LIGHT DETECTION APPARATUS AND METHOD OF MANUFACTURING THE SAME

(71) Applicant: SONY SEMICONDUCTOR SOLUTIONS CORPORATION, KANAGAWA (JP)

(72) Inventors: MASAHIKO ONO, KUMAMOTO (JP); TAKESHI YOSHOU, KUMAMOTO (JP); HIDEKI OSAMURA, KUMAMOTO (JP)

(21) Appl. No.: 19/486,685

(22) PCT Filed: May 21, 2024
(86) PCT No.: PCT/JP2024/018699

§ 371 Date: Nov. 21, 2025

(30) Foreign Application Priority Data
May 30, 2023 (JP) 2023-088937

(51) Int. Cl. H10F 39/00

(52) U.S. Cl. CPC H10F 39/805; H10F 39/014

(57) ABSTRACT

Provided are a light detection apparatus capable of suppressing deterioration in characteristic and a method of manufacturing the same. A light detection apparatus includes a semiconductor layer, a pixel provided in the semiconductor layer, the insulating film provided on the semiconductor layer, the insulating film that covers the pixel, and an electrode disposed in an opening provided on the insulating film. The pixel includes a photoelectric conversion unit, a floating diffusion that accumulates a charge generated in the photoelectric conversion unit, and a transfer transistor that transfers the charge generated in the photoelectric conversion unit to the floating diffusion. The opening includes a first opening opened on a surface of the insulating film and a second opening opened on a bottom surface of the first opening and having a diameter smaller than that of the first opening. The floating diffusion is located below a bottom surface of the second opening. An electrode is connected to the floating diffusion via the second opening.

### TECHNICAL FIELD

The present disclosure relates to a light detection apparatus and a method of manufacturing the same.

### BACKGROUND ART

A CMOS image sensor is known in which a plurality of pixels (for example, four pixels) is made one shared unit, a plurality of pixels forming one shared unit is arrayed in a two-dimensional array, and a plurality of pixels forming one shared unit shares one floating diffusion (refer to, for example, Patent Document 1). The floating diffusion is arranged at the center surrounded by four pixels, for example, and is connected to a source of a reset transistor and a gate of an amplification transistor via connection wiring.

### CITATION LIST

### Patent Document

Patent Document 1: Japanese Patent Application Laid-Open No. 2011-71347

### SUMMARY OF THE INVENTION

### Problems to be Solved by the Invention

With miniaturization of a pixel region, a space between a floating diffusion and another region (for example, an impurity region for isolation between elements or a gate of a transfer transistor) is getting narrow. As the narrowing progresses, a strong electric field is likely to be generated between the floating diffusion and another region, and noise such as a white spot is likely to be generated due to the strong electric field, which might cause deterioration in characteristic of the CMOS image sensor.

The present disclosure has been made in view of such circumstances, and an object thereof is to provide a light detection apparatus capable of suppressing deterioration in characteristic and a method of manufacturing the same.

### Solutions to Problems

A light detection apparatus according to one aspect of the present disclosure includes a semiconductor layer, a pixel provided in the semiconductor layer, an insulating film provided on the semiconductor layer, the insulating film that covers the pixel, and an electrode disposed in an opening provided in the insulating film. The pixel includes a photoelectric conversion unit, a floating diffusion that accumulates a charge generated in the photoelectric conversion unit, and a transfer transistor that transfers the charge generated in the photoelectric conversion unit to the floating diffusion. The opening includes a first opening opened on a surface of the insulating film and a second opening opened on a bottom surface of the first opening and having a diameter smaller than that of the first opening. The floating diffusion is located below a bottom surface of the second opening. The electrode is connected to the floating diffusion via the second opening.

With this arrangement, out of the electrode arranged in the opening, a diameter of a portion (for example, a lower portion) in contact with the floating diffusion can be made smaller than that of the other portion. With this arrangement, a width of the floating diffusion can be reduced in a direction parallel to a front surface of the semiconductor layer, and a distance between the floating diffusion and the other region (for example, a region having a potential different from that of the floating diffusion) can be easily secured. The longer the distance, the easier it is to relax an electric field generated between the floating diffusion and the other region. For example, since generation of noise such as a white spot caused by a strong electric field can be suppressed, an imaging apparatus can suppress deterioration in characteristic.

### BRIEF DESCRIPTION OF DRAWINGS

FIG. 1 is a block diagram illustrating a configuration example of an imaging apparatus according to an embodiment of the present disclosure.

FIG. 2 is a circuit diagram illustrating a configuration example of a shared pixel unit of the imaging apparatus according to the embodiment of the present disclosure.

FIG. 3 is a plan view illustrating a layout example of the shared pixel unit of the imaging apparatus according to the embodiment of the present disclosure.

FIG. 4 is a cross-sectional view illustrating a configuration example of a first floating diffusion of the imaging apparatus according to the embodiment of the present disclosure and a periphery thereof.

FIG. 5 is a cross-sectional view illustrating a configuration example of a second floating diffusion of the imaging apparatus according to the embodiment of the present disclosure and a periphery thereof.

FIG. 6A is a cross-sectional view illustrating a manufacturing method example 1 of the imaging apparatus according to the embodiment of the present disclosure in order of steps.

FIG. 6B is a cross-sectional view illustrating a manufacturing method example 1 of the imaging apparatus according to the embodiment of the present disclosure in order of steps.

FIG. 6C is a cross-sectional view illustrating a manufacturing method example 1 of the imaging apparatus according to the embodiment of the present disclosure in order of steps.

FIG. 6D is a cross-sectional view illustrating a manufacturing method example 1 of the imaging apparatus according to the embodiment of the present disclosure in order of steps.

FIG. 6E is a cross-sectional view illustrating a manufacturing method example 1 of the imaging apparatus according to the embodiment of the present disclosure in order of steps.

FIG. 7A is a cross-sectional view illustrating a manufacturing method example 2 of the imaging apparatus according to the embodiment of the present disclosure in order of steps.

FIG. 7B is a cross-sectional view illustrating a manufacturing method example 2 of the imaging apparatus according to the embodiment of the present disclosure in order of steps.

FIG. 7C is a cross-sectional view illustrating a manufacturing method example 2 of the imaging apparatus according to the embodiment of the present disclosure in order of steps.

FIG. 8 is a cross-sectional view illustrating a modification of the manufacturing method example 2 according to the embodiment of the present disclosure.

FIG. 9A is a cross-sectional view illustrating a manufacturing method example 3 of the imaging apparatus according to the embodiment of the present disclosure in order of steps.

FIG. 9B is a cross-sectional view illustrating a manufacturing method example 3 of the imaging apparatus according to the embodiment of the present disclosure in order of steps.

### MODE FOR CARRYING OUT THE INVENTION

Hereinafter, embodiments of the present disclosure will be described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between respective layers and the like are different from actual ones. Therefore, specific thicknesses and dimensions should be determined in consideration of the following description. Furthermore, it is needless to say that portions having different dimensional relationships and ratios are included between the drawings.

Definitions of directions such as upward and downward in the following description are merely definitions for convenience of description, and do not limit the technical idea of the present disclosure. For example, it goes without saying that when an object is observed while being rotated by 90°, the up and down are converted into left and right, and when the object is observed while being rotated by 180°, the up and down are inverted.

In the following description, there will be a case where directions are described using terms such as an X-axis direction, a Y-axis direction, and a Z-axis direction. For example, the X-axis direction and the Y-axis direction are directions parallel to a front surface 11a of a semiconductor substrate 11. The X-axis direction and the Y-axis direction will also be referred to as a horizontal direction. The Z-axis direction is a normal direction of the front surface 11a of the semiconductor substrate 11, and is also a thickness direction of the semiconductor substrate 11. The X-axis direction, the Y-axis direction, and the Z-axis direction are orthogonal to one another.

Furthermore, in the following description, “plan view” means, for example, a diagram as seen in the thickness direction (for example, in the Z-axis direction) of the semiconductor substrate 11.

### Embodiment

### Overall Configuration Example of Imaging Apparatus

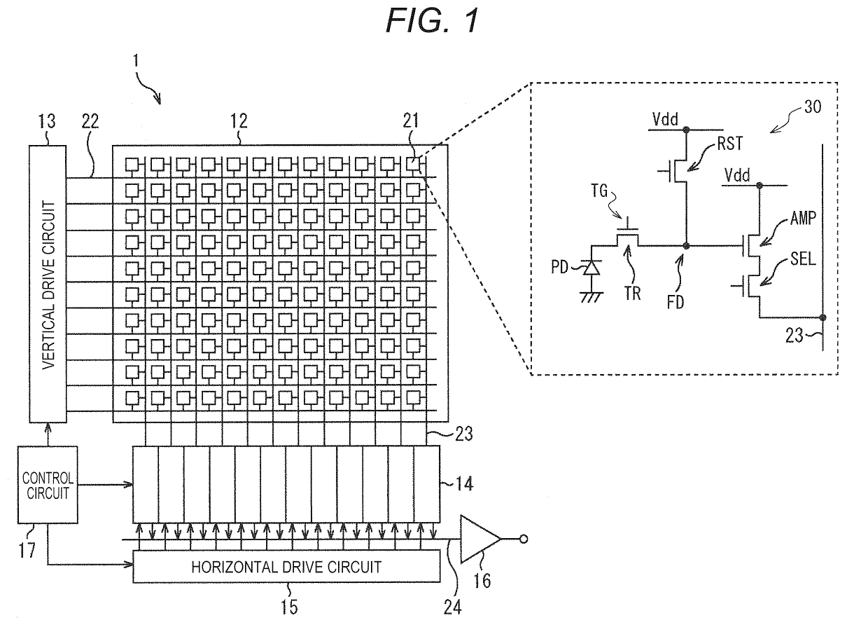

FIG. 1 is a block diagram illustrating a configuration example of an imaging apparatus 1 (an example of a “light detection apparatus” of the present disclosure) according to an embodiment of the present disclosure. As illustrated in FIG. 1, the imaging apparatus 1 includes a pixel region 12 provided in a semiconductor substrate, a vertical drive circuit 13, a column signal processing circuit 14, a horizontal drive circuit 15, an output circuit 16, and a control circuit 17. The vertical drive circuit 13, the column signal processing circuit 14, the horizontal drive circuit 15, the output circuit 16, and the control circuit 17 may be provided in the semiconductor substrate, or may be provided in a second semiconductor substrate disposed on a front surface side of a (first) semiconductor substrate via a multilayer wiring layer including a wiring layer and an interlayer insulating film (none of them is illustrated).

The pixel region 12 is a light-receiving region that receives light condensed by an optical system not illustrated, and includes a plurality of pixels 21. The plurality of pixels 21 is arranged in a matrix. The plurality of pixels 21 is connected to the vertical drive circuit 13 for each row via the horizontal signal lines 22, and is connected to the column signal processing circuit 14 for each column via the vertical signal lines 23. The plurality of pixels 21 outputs pixel signals at levels corresponding to amounts of light respectively received. An image of a subject is constructed from these pixel signals.

The vertical drive circuit 13 sequentially supplies drive signals for driving (transferring, selecting, resetting and the like) the respective pixels 21 for each row of the plurality of pixels 21 to the pixels 21 via the horizontal signal lines 22. By performing correlated double sampling (CDS) processing on the pixel signals output from the plurality of pixels 21 via the vertical signal lines 23, the column signal processing circuit 14 performs AD conversion on the pixel signals and removes reset noise.

The horizontal drive circuit 15 sequentially supplies the column signal processing circuit 14 with drive signals for causing the column signal processing circuit 14 to output the pixel signals to a data output signal line 24 for each column of the plurality of pixels 21. The output circuit 16 amplifies the pixel signals supplied from the column signal processing circuit 14 via the data output signal line 24 at a timing according to the drive signals of the horizontal drive circuit 15, and outputs the same to a signal processing circuit of a subsequent stage. The control circuit 17 controls driving of respective blocks inside the imaging apparatus 1. For example, the control circuit 17 generates a clock signal according to a drive cycle of each block and supplies the same to the respective blocks.

The pixel 21 includes a photodiode PD (an example of a “photoelectric conversion unit” of the present disclosure), a transfer transistor TR, a floating diffusion FD, an amplification transistor AMP, a selection transistor SEL, and a reset transistor RST. The transfer transistor TR, the floating diffusion FD, the amplification transistor AMP, the selection transistor SEL, and the reset transistor RST form a read circuit 30 that reads a charge (pixel signal) photoelectrically converted by the photodiode PD.

The photodiode PD is a photoelectric conversion unit that converts incident light into a charge through photoelectric conversion to accumulate, an anode terminal of which is grounded and a cathode terminal of which is connected to the transfer transistor TR. A transfer signal is supplied from the vertical drive circuit 13 to a gate electrode TG of the transfer transistor TR. The transfer transistor TR is driven in accordance with the transfer signal supplied to the transfer gate TG. Hereinafter, the gate electrode TG is also referred to as a transfer gate. When the transfer transistor TR is turned on, the charge accumulated in the photodiode PD is transferred to the floating diffusion FD. The floating diffusion FD, which is a floating diffusion region having a predetermined accumulation capacity connected to a gate electrode of the amplification transistor AMP, temporarily accumulates the charge transferred from the photodiode PD.

The amplification transistor AMP outputs the pixel signal at a level (that is, a potential of the floating diffusion FD) corresponding to the charge accumulated in the floating diffusion FD to the vertical signal line 23 via the selection transistor SEL. That is, with the configuration in which the floating diffusion FD is connected to the gate electrode of the amplification transistor AMP, the floating diffusion FD and the amplification transistor AMP function as a conversion unit that amplifies the charge generated in the photodiode PD and converts the same into the pixel signal at a level corresponding to the charge.

The selection transistor SEL is driven in accordance with a selection signal supplied from the vertical drive circuit 13, and when the selection transistor SEL is turned on, the pixel signal output from the amplification transistor AMP is put into a state capable of being output to the vertical signal line 23.

The reset transistor RST is driven in accordance with a reset signal supplied from the vertical drive circuit 13, and when the reset transistor RST is turned on, the charge accumulated in the floating diffusion FD is discharged to a power supply line Vdd, and the floating diffusion FD is reset.

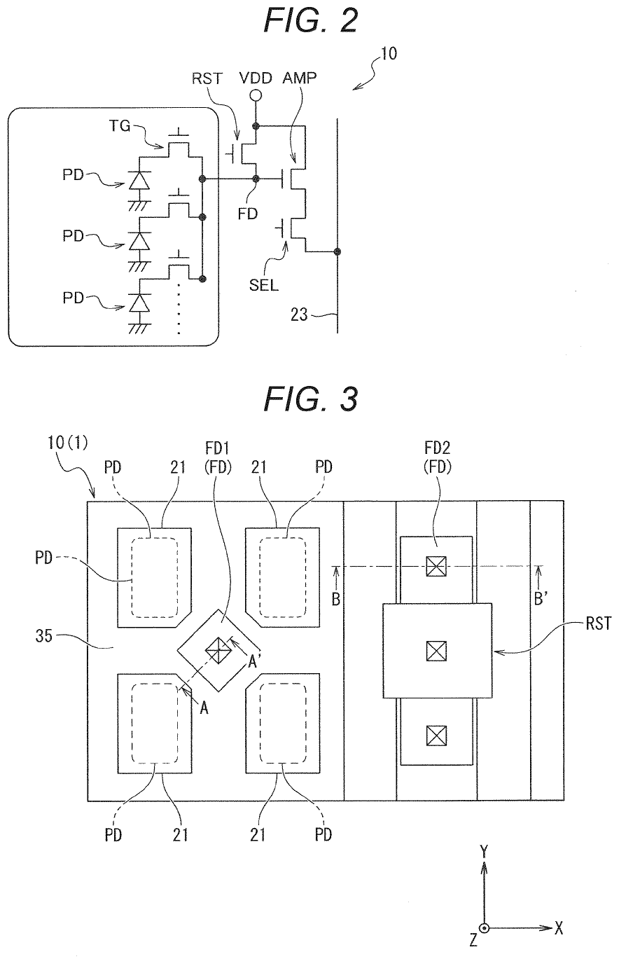

FIG. 2 is a circuit diagram illustrating a configuration example of a shared pixel unit 10 of the imaging apparatus 1 according to the embodiment of the present disclosure. As illustrated in FIG. 2, in the imaging apparatus 1, the photodiodes PD and the transfer transistors TR of the plurality of pixels 21 may be connected in parallel to form the shared pixel unit 10. In the shared pixel unit 10, for example, the photodiode PD of each pixel 21 included in the shared pixel unit 10 is connected to one floating diffusion FD via the transfer transistor TR of each pixel 21. Note that, the number of pixels 21 included in the shared pixel unit 10 is not particularly limited, but is four, for example.

### Layout Example of Pixel Sharing Unit

FIG. 3 is a plan view illustrating a layout example of the shared pixel unit 10 of the imaging apparatus 1 according to the embodiment of the present disclosure. Note that, FIG. 3 illustrates the layout example of the pixel 21 including the photodiode PD, the floating diffusion FD, and the selection transistor SEL, and the transfer transistor TR, the selection transistor SEL, and the amplification transistor AMP illustrated in FIG. 2 are not illustrated.

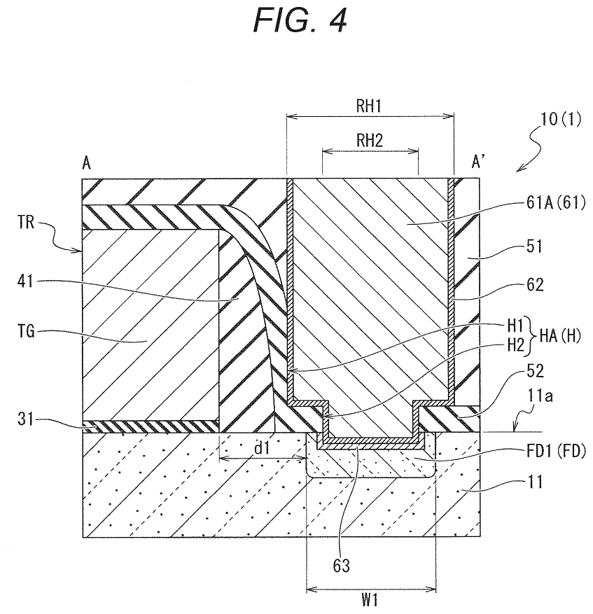

As illustrated in FIG. 3, in the imaging apparatus 1, for example, a total of four pixels 21, which are two pixels arrayed in the vertical direction and two pixels arrayed in the horizontal direction, form one shared pixel unit 10. One shared pixel structure includes four photodiodes PD (an example of the “photoelectric conversion unit” of the present disclosure), four transfer transistors TR (refer to FIG. 2), one shared floating diffusion FD, one shared selection transistor SEL (refer to FIG. 2), one shared reset transistor RST (refer to FIG. 2 and FIG. 4 to be described later), and one shared amplification transistor AMP (refer to FIG. 2).

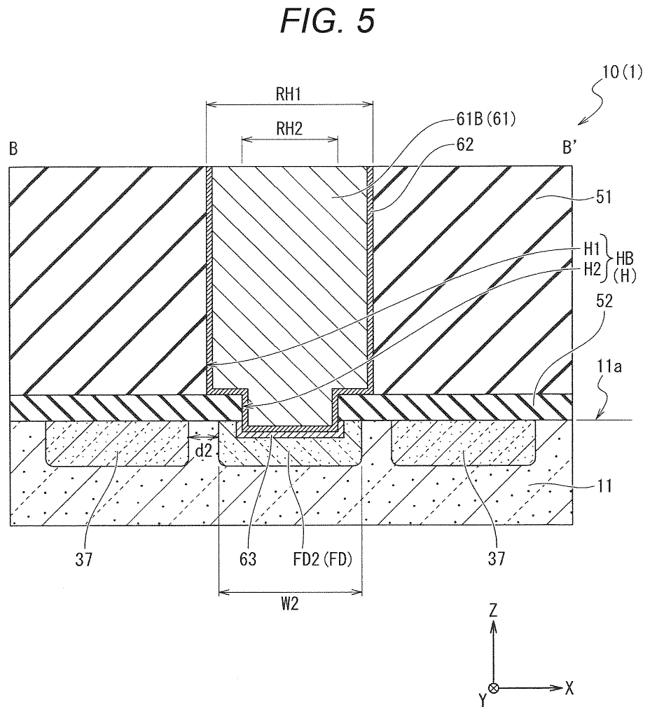

The floating diffusion FD is disposed in the central portion of the four pixels 21 forming one shared pixel unit 10. The transfer gate TG (refer to FIG. 2 and FIG. 4 to be described later) is disposed in the vicinity of the floating diffusion FD. For example, the floating diffusion FD includes a first floating diffusion FD1 disposed in the central portion of the four pixels 21 and a second floating diffusion FD2 serving as a source of the reset transistor RST. The first floating diffusion FD1 and the second floating diffusion FD2 are connected to each other via electrodes 61A and 61B (refer to FIGS. 4 and 5) to be described later and the wiring layer included in the multilayer wiring layer.

A pixel isolation portion 35 is provided on an outer periphery of the four pixels 21. The pixel isolation portion 35 includes, for example, an impurity region of a conductivity type different from that of the semiconductor substrate 11 (an example of a “semiconductor layer” of the present disclosure), deep trench isolation or the like.

In FIG. 3, an upper side in a vertical direction of a paper surface is a front surface side of the semiconductor substrate 11, on which a multilayer wiring layer including a plurality of wiring layers and an interlayer insulating film (none of them is illustrated) is provided. In contrast, in FIG. 3, a lower side in the vertical direction of the paper surface is a back surface side of the semiconductor substrate 11, and is a light incident surface on which light is incident, on which an on-chip lens, a color filter and the like (none of them is illustrated) are provided. The imaging apparatus 1 is a back-illuminated CMOS image sensor that photoelectrically converts light incident from the back surface side of the semiconductor substrate 11.

### Configuration Example of Floating Diffusion and Periphery Thereof

FIG. 4 is a cross-sectional view illustrating a configuration example of the first floating diffusion FD1 of the imaging apparatus 1 according to the embodiment of the present disclosure and a periphery thereof. FIG. 4 schematically illustrates a cross section taken along line A-A′ of the plan view illustrated in FIG. 3. FIG. 5 is a cross-sectional view illustrating a configuration example of the second floating diffusion FD2 of the imaging apparatus 1 according to the embodiment of the present disclosure and a periphery thereof. FIG. 5 illustrates a cross section taken along line B-B′ of the plan view illustrated in FIG. 3.

In FIGS. 4 and 5, the semiconductor substrate 11 is, for example, a single crystal silicon substrate or a single crystal silicon layer formed on a substrate not illustrated by an epitaxial growth method.

The transfer transistor TR (refer to FIG. 2) is provided, for example, from the inside of the semiconductor substrate 11 to the front surface 11a (an example of the “first surface” of the present disclosure). The transfer transistor TR is, for example, an N-type vertical transistor including the gate electrode (transfer gate) TG and a gate insulating film 31 provided between the transfer gate TG and the semiconductor substrate 11, and including the photodiode PD (refer to FIG. 3) as a source and the floating diffusion FD as a drain. The transfer transistor TR transfers a charge e-generated in the photodiode PD from the photodiode PD to the floating diffusion FD.

The floating diffusion FD is provided on the front surface 11a side of the semiconductor substrate 11, and is formed by, for example, an N-type impurity diffusion layer. The floating diffusion FD accumulates the charge e-transferred from the transfer transistor TR.

As illustrated in FIG. 3, the floating diffusion FD includes the first floating diffusion FD1 disposed in the central portion of the four pixels 21 and the second floating diffusion FD2 serving as the source of the reset transistor RST. The first floating diffusion FD1 and the second floating diffusion FD2 are connected to each other via, for example, the electrode 61A that penetrates an interlayer insulating film 51 illustrated in FIG. 4 and is connected to the first floating diffusion FD1, the electrode 61B that penetrates the interlayer insulating film 51 illustrated in FIG. 5 and is connected to the second floating diffusion FD2, and a wiring layer (not illustrated) connected to these electrodes 61A and 61B.

A configuration example of the floating diffusion FD and the periphery thereof will be described in further detail with reference to FIGS. 4 and 5. As illustrated in FIGS. 4 and 5, an insulating film 52 (an example of a “second insulating film” of the present disclosure) is provided on the front surface 11a side of the semiconductor substrate 11. The insulating film 52 is, for example, a silicon nitride film (SiN film).

As illustrated in FIG. 4, the first floating diffusion FD1 is provided adjacent to the transfer transistor TR. In the vicinity of the first floating diffusion FD1, the transfer gate TG and an insulating sidewall 41 covering a side surface of the transfer gate TG are provided. The transfer gate TG and the insulating sidewall 41 covering the side surface thereof are covered with the insulating film 52. Furthermore, the first floating diffusion FD1 is also covered with the insulating film 52 except for a region located immediately below a second opening H2 to be described later.

Furthermore, as illustrated in FIG. 5, the second floating diffusion FD2 is provided adjacent to a P-type impurity region 37 for element isolation. For example, the impurity regions 37 are provided on both sides of the second floating diffusion FD2 in the X-axis direction. The second floating diffusion FD2 and the impurity region 37 are separated from each other. The impurity region 37 is covered with the insulating film 52. Furthermore, the second floating diffusion FD2 is also covered with the insulating film 52 except for a region located immediately below the second opening H2 to be described later.

As illustrated in FIGS. 4 and 5, the interlayer insulating film 51 (an example of a “first insulating film” of the present disclosure) is provided on the insulating film 52. The interlayer insulating film 51 is, for example, a silicon oxide film (SiO film). The pixel region 12 (refer to FIG. 1) including a plurality of pixels 21 is covered with the interlayer insulating film 51. The interlayer insulating film 51 is provided with a plurality of openings H, and the electrode 61 is disposed in the openings H.

### (1) Regarding First Floating Diffusion FD1 and Periphery Thereof

For example, as illustrated in FIG. 4, an opening HA is provided on the first floating diffusion FD1. The opening HA includes a first opening H1 that opens on a surface of the interlayer insulating film 51 and a second opening H2 that opens on a bottom surface of the first opening H1 and has a diameter smaller than that of the first opening H1. The first opening H1 is provided on the interlayer insulating film 51. The second opening H2 is provided on the insulating film 52. When a diameter of the first opening H1 is set to RH1 and a diameter of the second opening H2 is set to R2, RH1>RH2 holds. The first floating diffusion FD1 is located below a bottom surface of the second opening H2.

In the opening HA, the electrode 61A is disposed with a barrier metal layer 62 interposed therebetween. The electrode 61A is formed using, for example, tungsten (W). The barrier metal layer 62 is formed using, for example, a lamination film obtained by stacking titanium nitride (TiN) on titanium (Ti). The barrier metal layer 62 and an alloy layer 63 of the barrier metal layer 62 and the semiconductor substrate 11 are provided between the electrode 61A and the first floating diffusion FD1. The alloy layer 63 mainly contains, for example, titanium silicide (TiSi) formed by reaction between Si forming the semiconductor substrate 11 and Ti forming the barrier metal layer 62.

The first floating diffusion FD1 is provided so as to cover the alloy layer 63 formed at the bottom of the opening HA. The alloy layer 63 is provided only inside the first floating diffusion FD1.

Assuming that a length (width) of the first floating diffusion FD1 is W1 in one direction parallel to the front surface 11a of the semiconductor substrate 11, the length (width) W1 is larger than the diameter RH2 of the second opening H2 and smaller than the diameter RH1 of the first opening H1. RH2<W1<RH1 holds.

The first floating diffusion FD1 needs to be formed so as to cover the alloy layer 63. Therefore, for example, in a case where the opening on the first floating diffusion includes only the first opening H1 (hereinafter, Comparative Example 1), it is necessary to widen the first floating diffusion toward the transfer gate TG. In Comparative Example 1, since the length (width) in the horizontal direction of the first floating diffusion needs to be longer than the diameter RH1 of the first opening H1, it is difficult to secure a long distance d1 in the horizontal direction between the first floating diffusion and the transfer gate TG.

In contrast, in the imaging apparatus 1 according to the present embodiment, as illustrated in FIG. 4, the opening HA includes the first opening H1 and the second opening H2 having a diameter smaller than that of the first opening H1. Since the electrode 61A is connected to the first floating diffusion FD1 via the second opening H2, the length of the alloy layer 63 in the horizontal direction can be shortened. With this arrangement, the length (width) W1 in the horizontal direction of the first floating diffusion FD1 that needs to be formed so as to cover the alloy layer 63 can be shortened, and for example, can be made shorter than the diameter RH1 of the first opening H1. The distance d1 between the first floating diffusion FD1 and the transfer gate TG can be easily secured by an amount by which the length (width) W1 is shortened. The longer the distance d1, the easier it is to relax an electric field generated between the first floating diffusion FD1 and the transfer gate TG.

### (2) Regarding Second Floating Diffusion FD2 and Periphery Thereof

As illustrated in FIG. 5, the second floating diffusion FD2, and an opening HB and the electrode 61B arranged thereon have configurations similar to those of the first floating diffusion FD1 and the opening HA and the electrode 61A arranged thereon described in (1) described above.

For example, as illustrated in FIG. 5, the opening HB is provided on the second floating diffusion FD2. The opening HB includes a first opening H1 that opens on a surface of the interlayer insulating film 51 and a second opening H2 that opens on a bottom surface of the first opening H1 and has a diameter smaller than that of the first opening H1. The first opening H1 is provided on the interlayer insulating film 51. The second opening H2 is provided on the insulating film 52. When a diameter of the first opening H1 is set to RH1 and a diameter of the second opening H2 is set to R2, RH1>RH2 holds. The second floating diffusion FD2 is located below the bottom surface of the second opening H2.

In the opening HB, the electrode 61B is disposed with the barrier metal layer 62 interposed therebetween. The electrode 61B is formed using, for example, tungsten (W). The barrier metal layer 62 and the alloy layer 63 are provided between the electrode 61B and the second floating diffusion FD2.

The second floating diffusion FD2 is provided so as to cover the alloy layer 63 formed at the bottom of the opening HB. The alloy layer 63 is provided only inside the second floating diffusion FD2.

When a length (width) of the second floating diffusion FD2 is W2 in one direction parallel to the front surface 11a of the semiconductor substrate 11, the length (width) W2 is larger than the diameter RH2 of the second opening H2 and smaller than the diameter RH1 of the first opening H1. RH2<W2<RH1 holds.

The second floating diffusion FD2 needs to be formed so as to cover the alloy layer 63. Therefore, for example, in a case where the opening on the second floating diffusion includes only the first opening H1 (hereinafter, Comparative Example 2), it is necessary to widen the second floating diffusion toward the impurity region 37 for element isolation. In Comparative Example 2, since the length (width) in the horizontal direction of the second floating diffusion needs to be longer than the diameter RH1 of the first opening H1, it is difficult to secure a long distance d2 in the horizontal direction between the second floating diffusion and the impurity region 37.

In contrast, in the imaging apparatus 1 according to the present embodiment, as illustrated in FIG. 5, the opening HB includes the first opening H1 and the second opening H2 having the diameter smaller than that of the first opening H1. Since the electrode 61B is connected to the second floating diffusion FD2 via the second opening H2, the length of the alloy layer 63 in the horizontal direction can be shortened. With this arrangement, the length (width) W2 in the horizontal direction of the second floating diffusion FD2 that needs to be formed so as to cover the alloy layer 63 can be shortened, and for example, can be made shorter than the diameter RH1 of the first opening H1. The distance d2 between the second floating diffusion FD2 and the impurity region 37 can be easily secured by an amount by which the length (width) W2 described above is shortened. The longer the distance d2, the easier it is to relax the electric field generated between the second floating diffusion FD2 and the impurity region 37.

### Manufacturing Method

Next, as a method of manufacturing the imaging apparatus 1 according to the embodiment of the present disclosure, a method of forming the opening H and the electrode 61 will be described. Here, three methods (manufacturing method examples 1 to 3) will be described. Note that, in the manufacturing method described below, the opening HA illustrated in FIG. 4 and the opening HB illustrated in FIG. 5 are simultaneously formed in the same process. Furthermore, the electrode 61A illustrated in FIG. 4 and the electrode 61B illustrated in FIG. 5 are simultaneously formed in the same process. The methods of forming the openings HA and HB are the same, and the methods of forming the electrodes 61A and 61B are also the same. Therefore, in the following description, the opening HB out of the openings HA and HB and the electrode 61B out of the electrodes 61A and 61B will be described as an example.

Furthermore, the imaging apparatus 1 is manufactured using various apparatuses such as a film deposition apparatus (including a chemical vapor deposition (CVD) apparatus, an atomic layer deposition (ALD) apparatus, and a sputtering apparatus), an etching apparatus, and a chemical mechanical polishing (CMP) apparatus. These apparatuses will be collectively referred to as manufacturing apparatuses.

### (1) Manufacturing Method Example 1

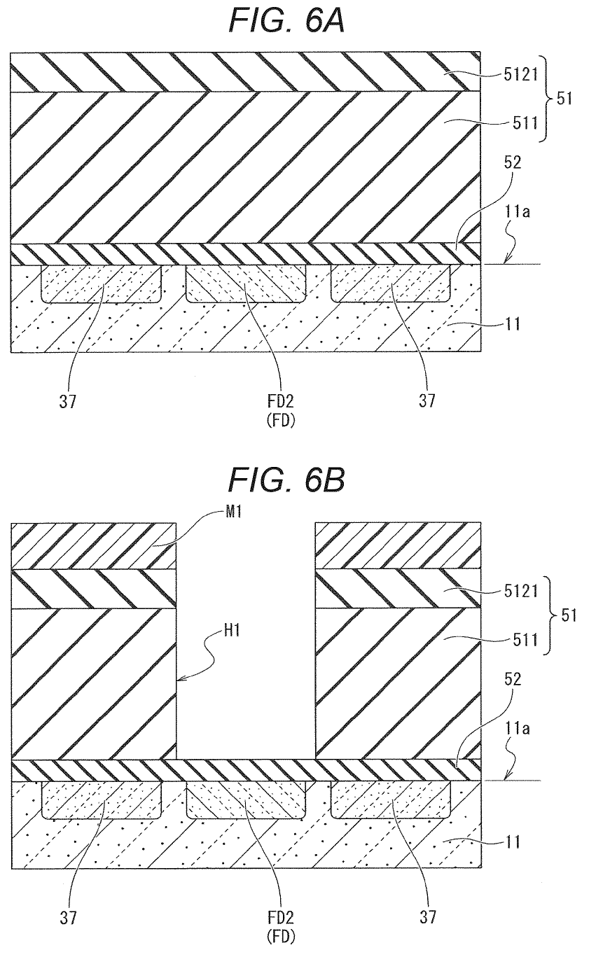

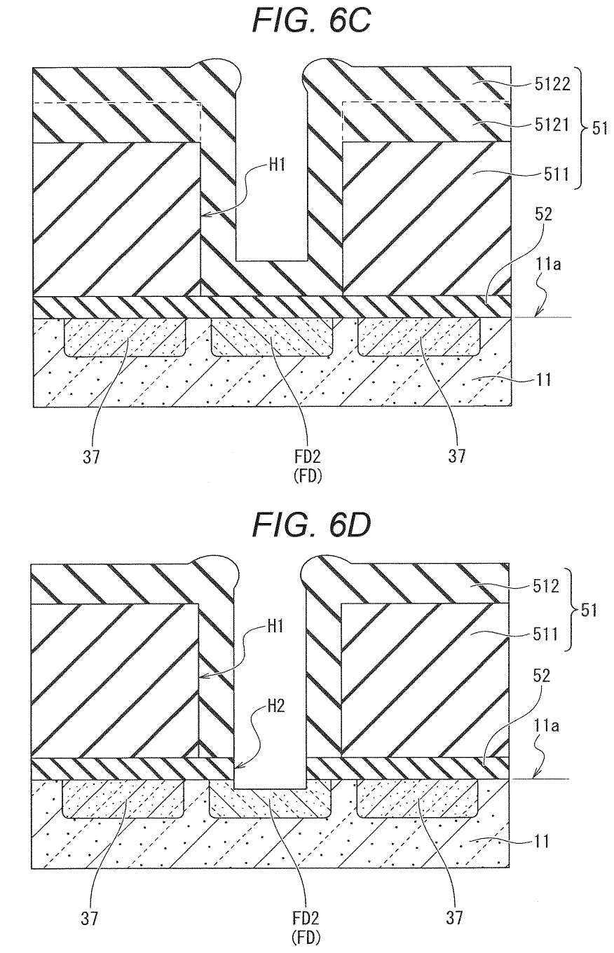

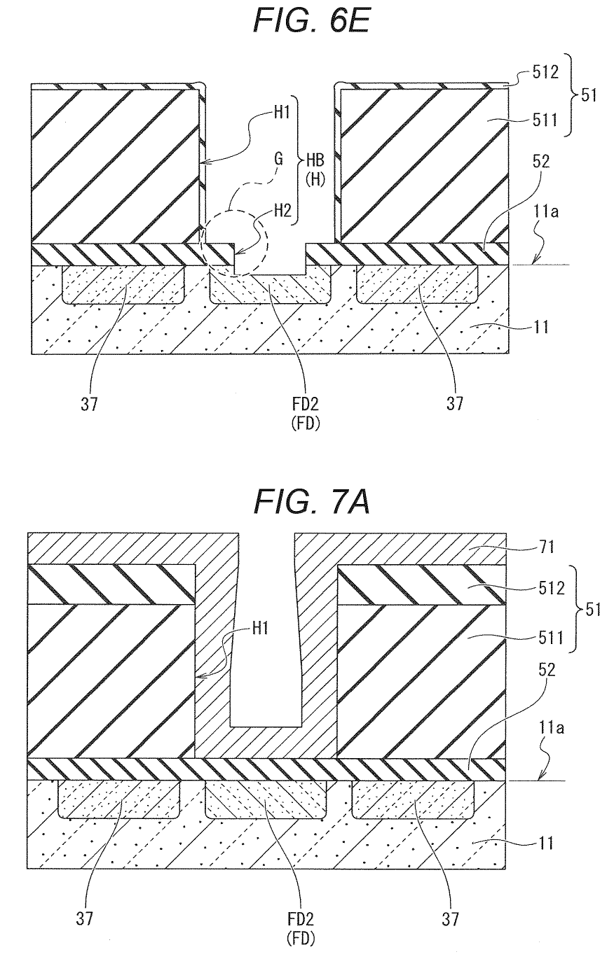

FIGS. 6A to 6E are cross-sectional views illustrating a manufacturing method example 1 of the imaging apparatus 1 according to the embodiment of the present disclosure in order of steps. In FIG. 6A, the second floating diffusion FD2 (hereinafter, simply referred to as a floating diffusion FD) and the impurity region 37 for element isolation are formed in the semiconductor substrate 11.

In FIG. 6A, the manufacturing apparatus deposits the insulating film 52 on the front surface 11a of the semiconductor substrate 11 in which the floating diffusion FD and the impurity region 37 for element isolation are formed. The insulating film 52 is, for example, a SIN film and is deposited by a CVD method.

Next, the manufacturing apparatus deposits the interlayer insulating film 51 on the insulating film 52. The interlayer insulating film 51 is, for example, a Sio film. The manufacturing apparatus deposits the Sio film 511 to be a first layer of the interlayer insulating film 51 by using the CVD method. Next, the manufacturing apparatus deposits a Sio film 5121 to be a second layer of the interlayer insulating film 51 using an ALD method. The ALD method can deposit the Sio film to have a denser and harder film quality than the CVD method.

Next, as illustrated in FIG. 6B, the manufacturing apparatus forms a mask M1 on the Sio film 5121 using a photolithography technique. The mask M1 includes, for example, a photoresist. The mask M1 has a shape that exposes a predetermined region where the first opening H1 is to be formed and covers other regions.

Next, the manufacturing apparatus performs dry etching of the Sio film 5121 and the SiO film 511 in this order using the mask M1 to form the first opening H1. As described above, the insulating film 52 is, for example, the SiN film. Therefore, when dry etching is performed on the Sio film 5121 and the Sio film 511, the insulating film 52 functions as an etching stopper. The first opening H1, the bottom surface of which is the insulating film 52, is formed. After the first opening H1 is formed, the manufacturing apparatus removes the mask M1.

Next, as illustrated in FIG. 6C, the manufacturing apparatus deposits the Sio film 5122 on the front surface 11a side of the semiconductor substrate 11. The method of depositing the Sio film 5122 is, for example, the ALD method. The Sio film 5122 thickens the interlayer insulating film 51 and covers the side surface and the bottom surface of the first opening H1. In this manufacturing method example 1, the Sio film 5122 is an example of a “protective film” of the present disclosure.

Next, the manufacturing apparatus etches back the front surface 11a side of the semiconductor substrate 11. With this arrangement, as illustrated in FIG. 6D, the SiO film 5122 covering the bottom surface of the first opening H1 and the insulating film 52 located below the same are removed, and the second opening H2, of which the bottom surface is the floating diffusion FD, is formed in the insulating film 52. In the etch back, the bottom surface of the first opening H1 is more easily etched than the side surface of the first opening H1. Therefore, the formation of the second opening H2 progresses in a state in which the side surface of the first opening H1 is covered with the Sio film 5122, and a state in which the side surface of the first opening H1 is covered with the Sio film 5122 is maintained even after the second opening H2 is formed. Note that, in the subsequent steps, the Sio film 5121 and the Sio film 5122 are collectively referred to as a SiO film 512.

Next, the manufacturing apparatus performs wet etching of the Sio film 512 to thin the same using, for example, a solution containing hydrofluoric acid (HF). In the wet etching using HF, SiO is etched at a high rate, whereas SiN is not etched. Since the insulating film 52 is formed using SiN, the insulating film 52 is not etched. With this arrangement, as illustrated in FIG. 6E, a part of the Sio film 512 is removed from the side surface of the first opening H1, the diameter of the first opening H1 expands, and a step G is formed between the first opening H1 and the second opening H2.

Next, the manufacturing apparatus deposits the barrier metal layer 62 (refer to FIGS. 4 and 5) on the front surface 11a side of the semiconductor substrate 11 to cover the side surface and the bottom surface of the opening HB (hereinafter, simply referred to as the opening H). Next, the manufacturing apparatus deposits a metal film on the front surface 11a of the semiconductor substrate 11 to fill the opening H. The metal embedded in the opening H is tungsten (W), for example. Next, the manufacturing apparatus applies CMP processing on the metal film to remove the metal film from above the interlayer insulating film 51. With this arrangement, the electrode 61 (refer to FIGS. 4 and 5) is formed from the metal film. Through the above steps, the imaging apparatus 1 having the cross-sectional structure illustrated in FIGS. 4 and 5 is completed.

### (2) Manufacturing Method Example 2

In the manufacturing method example 1 described above, a case where the Sio film 5122 is used as the “protective film” of the present disclosure has been described. In a manufacturing method example 2, a case where a metal film is used as the “protective film” of the present disclosure will be described.

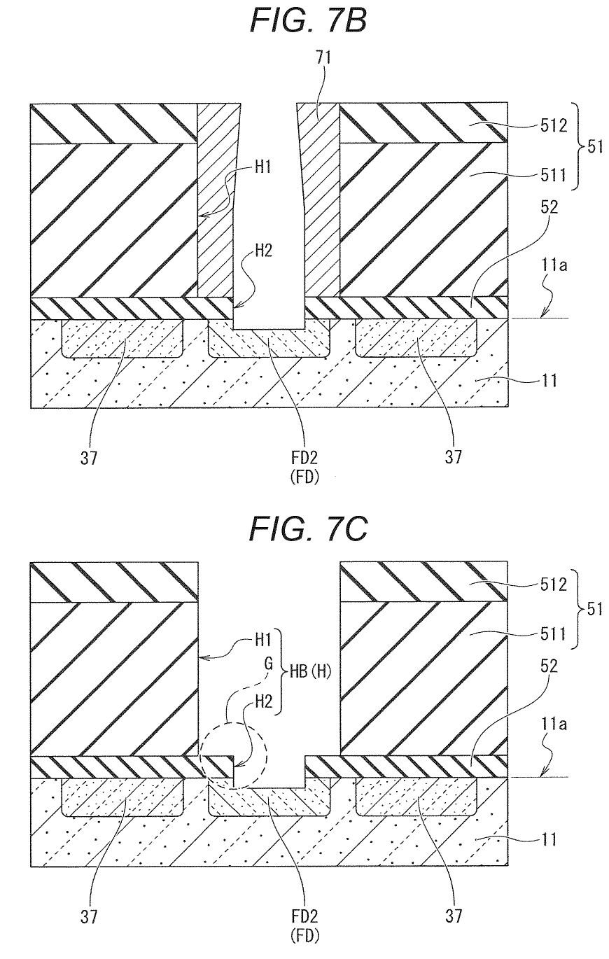

FIGS. 7A to 7C are cross-sectional views illustrating the manufacturing method example 2 of the imaging apparatus 1 according to the embodiment of the present disclosure in order of steps. In FIG. 7A, steps up to a step of forming the first opening H1 on the interlayer insulating film 51 are the same as those in the manufacturing method example 1. In the manufacturing method example 2, after the first opening Hl is formed, the manufacturing apparatus deposits a metal film 71 on the front surface 11a side of the semiconductor substrate 11. The method of depositing the metal film 71 is not particularly limited, and is, for example, a sputtering method or the CVD method. A type of the metal film 71 is not particularly limited. In the manufacturing method example 2, the metal film 71 is an example of the “protective film” of the present disclosure.

Next, the manufacturing apparatus etches back the front surface 11a side of the semiconductor substrate 11. With this arrangement, as illustrated in FIG. 7B, the metal film 71 covering the bottom surface of the first opening H1 and the insulating film 52 located below the same are removed, and the second opening H2, the bottom surface of which is the floating diffusion FD, is formed in the insulating film 52. In the etch back, the bottom surface of the first opening H1 is more easily etched than the side surface of the first opening H1. Therefore, the formation of the second opening H2 progresses in a state in which the side surface of the first opening H1 is covered with the metal film 71, and a state in which the side surface of the first opening H1 is covered with the metal film 71 is maintained even after the second opening H2 is formed.

Next, the manufacturing apparatus performs wet etching of the metal film 71 to remove the same using, for example, a solution containing sulfuric acid (H₂SO₄). In the wet etching using sulfuric acid, the metal film 71 is etched at a high rate, whereas the SiO films 511 and 512 and the insulating film 52 formed using SIN are not etched. With this arrangement, as illustrated in FIG. 7C, the metal film 71 is entirely removed from the side surface of the first opening H1, the diameter of the first opening H1 expands, and a step G is formed between the first opening H1 and the second opening H2.

Subsequent steps are the same as those in the manufacturing method example 1. The manufacturing apparatus deposits the barrier metal layer 62 (refer to FIGS. 4 and 5) on the front surface 11a side of the semiconductor substrate 11, deposits the metal film, and applies CMP processing on the metal film to form the electrode 61 (refer to FIGS. 4 and 5). Through the above steps, the imaging apparatus 1 having the cross-sectional structure illustrated in FIGS. 4 and 5 is completed.

### (2.1) Modification

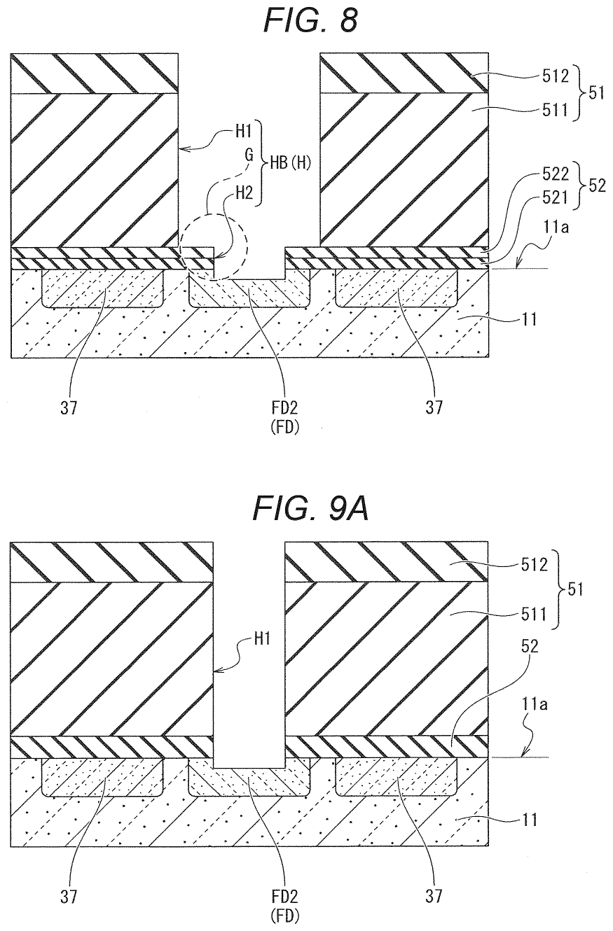

FIG. 8 is a cross-sectional view illustrating a modification of the manufacturing method example 2 according to the embodiment of the present disclosure. The insulating film 52 as an example of the second insulating film of the present disclosure is not limited to a single-layer film of SiN. As illustrated in FIG. 8, the insulating film 52 may be a laminated film obtained by stacking the SiN film 522 on the Sio film 521. Even with such a configuration, the second opening H2 can be formed in the insulating film 52.

Furthermore, when the metal film 71 (refer to FIG. 7B) covering the side surface of the first opening H1 is removed by wet etching using sulfuric acid (H₂SO₄), neither the Sio film 521 nor the SiN film 522 forming the insulating film 52 is etched. For example, when the metal film 71 is removed using sulfuric acid (H₂SO₄), the SiO film 521 under the SiN film 522 is not etched, and a gap is not formed between the SiN film 522 and the semiconductor substrate 11. Even in a case where the insulating film 52 is the laminated film as described above, the side surface of the second opening H2 can be formed flat as in the case of the single layer film.

### (3) Manufacturing Method Example 3

In the above-described manufacturing method examples 1 and 2, it has been described that the step G is formed between the first opening H1 and the second opening H2 by performing etch back in a state in which the side surface of the first opening H1 is covered with the protective film to form the second opening H2 and then removing the protective film. However, in the embodiment of the present disclosure, the method of forming the step G is not limited thereto. The step G may be formed using an etching selectivity between the interlayer insulating film 51 formed using SiO and the insulating film 52 formed using SiN.

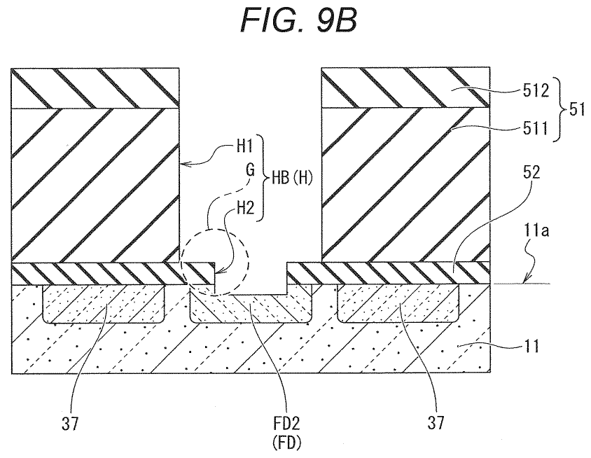

FIGS. 9A to 9B are cross-sectional views illustrating a manufacturing method example 3 of the imaging apparatus 1 according to the embodiment of the present disclosure in order of steps. In FIG. 9A, the manufacturing apparatus performs dry etching of the interlayer insulating film 51 using a mask not illustrated to form the first opening H1 and the second opening H2. In the manufacturing method example 3, the width of the first opening H1 is formed narrower than in the manufacturing method examples 1 and 2. More specifically, the first opening H1 is formed to have the same (or approximately the same) width as the second opening H2.

Next, the manufacturing apparatus performs wet etching of the interlayer insulating film 51 using, for example, a solution containing hydrofluoric acid (HF). Since the interlayer insulating film 51 is formed using SiO and the insulating film 52 is formed using SiN, the side surface of the first opening H1 is etched to increase the diameter of the first opening H1, but the side surface of the second opening H2 is not etched. With this arrangement, as illustrated in FIG. 9B, step G is formed between the first opening H1 and the second opening H2.

### Effect of Embodiment

As described above, the imaging apparatus 1 according to the embodiment of the present disclosure includes the semiconductor substrate 11, the pixel 21 provided in the semiconductor substrate 11, the interlayer insulating film 51 and the insulating film 52 that are provided on the semiconductor substrate 11 and cover the pixel 21, and the electrode 61 disposed in the opening H provided on the interlayer insulating film 51 and the insulating film 52. The pixel 21 includes the photodiode PD, the floating diffusion FD that accumulates the charge generated in the photodiode PD, and the transfer transistor TR that transfers the charge generated in the photodiode PD to the floating diffusion FD. The opening H includes the first opening H1 that opens on the surface of the interlayer insulating film 51 and the second opening H2 that opens on the bottom surface of the first opening H1 and has a diameter smaller than that of the first opening H1. The floating diffusion FD is located below the bottom surface of the second opening H2. The electrode 61 is connected to the floating diffusion FD via the second opening H2.

With this arrangement, in the electrode 61 disposed in the opening H, the diameter of the portion in contact with the floating diffusion FD (for example, lower portion) can be made smaller than the diameters of the other portions. With this arrangement, the width of the floating diffusion FD can be reduced in the direction parallel to the front surface of the semiconductor substrate 11, and the distance between the floating diffusion FD and the other region (for example, a region having a potential different from that of the floating diffusion FD) can be easily secured. Examples of the other regions include the transfer gate TG illustrated in FIG. 4 and the impurity region 37 for element isolation illustrated in FIG. 5.

For example, the longer the distance d1 illustrated in FIG. 4, the easier it is to relax an electric field generated between the first floating diffusion FD1 and the transfer gate TG. The longer the distance d2 illustrated in FIG. 5, the easier it is to relax the electric field generated between the second floating diffusion FD2 and the impurity region 37 for element isolation. For example, since the generation of noise such as a white spot caused by a strong electric field can be suppressed, the imaging apparatus 1 can suppress deterioration in characteristic. There is a possibility of contributing to the progress of further miniaturization of the imaging apparatus.

A method of manufacturing an imaging apparatus according to an embodiment of the present disclosure includes depositing an interlayer insulating film 51 and an insulating film 52 on a semiconductor substrate 11 provided with a floating diffusion FD, forming an opening H with the floating diffusion FD as a bottom surface on the interlayer insulating film 51 and the insulating film 52, and forming an electrode 61 in the opening H. The forming the opening H includes forming a first opening H1 that opens on a surface of the interlayer insulating film 51 and forming a second opening H2 that opens on a bottom surface of the first opening H1 and has a diameter smaller than that of the first opening H1. In forming the electrode 61, the electrode 61 is connected to the floating diffusion FD via the second opening H2. With this arrangement, the above-described imaging apparatus 1 can be manufactured.

### Other Embodiments

As described above, the present disclosure is described according to the embodiments and modifications thereof, but it should not be understood that the description and drawings forming a part of this disclosure limit the present disclosure. Various alternative embodiments, examples, and operation technologies will be apparent to those skilled in the art from this disclosure. It is a matter of course that the present technology includes various embodiments and the like not described herein. At least one of various omissions, substitutions, or changes of the components may be made without departing from the gist of the above-described embodiments and modifications. Furthermore, the effects described in the present specification are merely examples and not restrictive, and there may also be other effects.

Note that, the present disclosure can also have the following configurations.
(1)

A light detection apparatus including:
a semiconductor layer;
a pixel provided in the semiconductor layer;
an insulating film provided on the semiconductor layer, the insulating film that covers the pixel; and
an electrode disposed in an opening provided on the insulating film, in which
the pixel includes:
a photoelectric conversion unit;
a floating diffusion that accumulates a charge generated in the photoelectric conversion unit; and
a transfer transistor that transfers the charge generated in the photoelectric conversion unit to the floating diffusion,
the opening includes:
a first opening opened on a surface of the insulating film; and
a second opening opened on a bottom surface of the first opening and having a diameter smaller than a diameter of the first opening,
the floating diffusion is located below a bottom surface of the second opening, and
the electrode is connected to the floating diffusion via the second opening.
(2)

The light detection apparatus according to (1) described above, in which a length of the floating diffusion is larger than the diameter of the second opening and smaller than the diameter of the first opening in one direction parallel to a surface of the semiconductor layer.
(3)

The light detection apparatus according to (1) or (2) described above, further including:
a barrier metal layer provided between the electrode and the floating diffusion; and
an alloy layer of the barrier metal layer and the semiconductor layer, in which
the alloy layer is provided only inside the floating diffusion.
(4)

The light detection apparatus according to any one of (1) to (3) described above, in which
the insulating film includes:
a first insulating film; and
a second insulating film provided between the first insulating film and the semiconductor layer,
the first opening is provided on the first insulating film, and
the second opening is provided on the second insulating film.
(5)

The light detection apparatus according to (4) described above, in which
the first insulating film is a silicon oxide film, and
the second insulating film is a silicon nitride film or a laminated film obtained by stacking a silicon nitride film on a silicon oxide film.
(6) The light detection apparatus according to any one of (1) to (5) described above, in which
the floating diffusion includes
a first floating diffusion provided adjacent to the transfer transistor, and
the electrode is connected to the first floating diffusion via the second opening.
(7)

The light detection apparatus according to any one of (1) to (6) described above, further including:
an impurity region for pixel isolation provided in the semiconductor layer, in which
the floating diffusion includes
a second floating diffusion provided adjacent to the impurity region, and
the electrode is connected to the second floating diffusion via the second opening.
(8)

The light detection apparatus according to any one of (1) to (7) described above, further including:
a plurality of pixels, in which
the plurality of pixels shares one floating diffusion.
(9)

A method of manufacturing a light detection apparatus, the method including:
depositing an insulating film on a semiconductor layer provided with a floating diffusion;
forming an opening with the floating diffusion as a bottom surface on the insulating film; and
forming an electrode in the opening, in which
the forming the opening includes:
forming a first opening opened on a surface of the insulating film; and
forming a second opening opened on a bottom surface of the first opening and having a diameter smaller than a diameter of the first opening, and
in the forming the electrode, the electrode is connected to the floating diffusion via the second opening.
(10)

The method of manufacturing a light detection apparatus according to (9) described above, in which
the forming the opening further includes
covering a side surface of the first opening with a protective film before forming the second opening, and
in the forming the second opening, a bottom of the first opening is etched to form the second opening in a state in which the side surface of the first opening is covered with the protective film.
(11)

The method of manufacturing a light detection apparatus according to (10) described above, in which the forming the second opening is performed by etch back.
(12)

The method of manufacturing a light detection apparatus according to (10) or (11) described above, further including: removing at least a part of the protective film after forming the second opening.
(13)

The method of manufacturing a light detection apparatus according to (12) described above, in which
the protective film is a silicon oxide film, and
in the removing the protective film, wet etching is performed using a solution containing hydrofluoric acid.
(14)

The method of manufacturing a light detection apparatus according to (12), in which
the protective film is a metal film, and
in the removing the protective film, wet etching is performed using a solution containing sulfuric acid.

### REFERENCE SIGNS LIST

1 Imaging apparatus
10 Shared pixel unit
11 Semiconductor substrate
11a Front surface
12 Pixel region
13 Vertical drive circuit
14 Column signal processing circuit
15 Horizontal drive circuit
16 Output circuit
17 Control circuit
21 Pixel
22 Horizontal signal line
23 Vertical signal line
24 Data output signal line
30 Read circuit
31 Gate insulating film
35 Pixel isolation portion
37 Impurity region
41 Sidewall
51 Interlayer insulating film
52 Insulating film
61 Electrode
61A, 61B Electrode
62 Barrier metal layer
63 Alloy layer
71 Metal film
511, 512, 521, 5121, 5122 SiO film
522 SiN film
AMP Amplification transistor
FD Floating diffusion
FD1 First floating diffusion
FD2 Second floating diffusion
G Step
H Opening
H1 First opening
H2 Second opening
HA, HB Opening
M1 Mask
PD Photodiode
RST Reset transistor
SEL Selection transistor
TG Transfer gate
TG Gate electrode (transfer gate)
Vdd Power supply line

1. A light detection apparatus comprising:
a semiconductor layer;
a pixel provided in the semiconductor layer;
an insulating film provided on the semiconductor layer, the insulating film that covers the pixel; and
an electrode disposed in an opening provided on the insulating film, wherein
the pixel includes:
a photoelectric conversion unit;
a floating diffusion that accumulates a charge generated in the photoelectric conversion unit; and
a transfer transistor that transfers the charge generated in the photoelectric conversion unit to the floating diffusion,
the opening includes:
a first opening opened on a surface of the insulating film; and
a second opening opened on a bottom surface of the first opening and having a diameter smaller than a diameter of the first opening,
the floating diffusion is located below a bottom surface of the second opening, and
the electrode is connected to the floating diffusion via the second opening.

2. The light detection apparatus according to claim 1, wherein a length of the floating diffusion is larger than the diameter of the second opening and smaller than the diameter of the first opening in one direction parallel to a surface of the semiconductor layer.

3. The light detection apparatus according to claim 1, further comprising:
a barrier metal layer provided between the electrode and the floating diffusion; and
an alloy layer of the barrier metal layer and the semiconductor layer, wherein
the alloy layer is provided only inside the floating diffusion.

4. The light detection apparatus according to claim 1, wherein
the insulating film includes:
a first insulating film; and
a second insulating film provided between the first insulating film and the semiconductor layer,
the first opening is provided on the first insulating film, and
the second opening is provided on the second insulating film.

5. The light detection apparatus according to claim 4, wherein
the first insulating film is a silicon oxide film, and
the second insulating film is a silicon nitride film or a laminated film obtained by stacking a silicon nitride film on a silicon oxide film.

6. The light detection apparatus according to claim 1, wherein
the floating diffusion includes
a first floating diffusion provided adjacent to the transfer transistor, and
the electrode is connected to the first floating diffusion via the second opening.

7. The light detection apparatus according to claim 1, further comprising:
an impurity region for pixel isolation provided in the semiconductor layer, wherein
the floating diffusion includes
a second floating diffusion provided adjacent to the impurity region, and
the electrode is connected to the second floating diffusion via the second opening.

8. The light detection apparatus according to claim 1, further comprising:
a plurality of pixels, wherein
the plurality of pixels shares one floating diffusion.

9. A method of manufacturing a light detection apparatus, the method comprising:
depositing an insulating film on a semiconductor layer provided with a floating diffusion;
forming an opening with the floating diffusion as a bottom surface on the insulating film; and
forming an electrode in the opening, wherein the forming the opening includes:
forming a first opening opened on a surface of the insulating film; and
forming a second opening opened on a bottom surface of the first opening and having a diameter smaller than a diameter of the first opening, and
in the forming the electrode, the electrode is connected to the floating diffusion via the second opening.

10. The method of manufacturing a light detection apparatus according to claim 9, wherein
the forming the opening further includes
covering a side surface of the first opening with a protective film before forming the second opening, and
in the forming the second opening, a bottom of the first opening is etched to form the second opening in a state in which the side surface of the first opening is covered with the protective film.

11. The method of manufacturing a light detection apparatus according to claim 10, wherein the forming the second opening is performed by etch back.

12. The method of manufacturing a light detection apparatus according to claim 10, further comprising: removing at least a part of the protective film after forming the second opening.

13. The method of manufacturing a light detection apparatus according to claim 12, wherein
the protective film is a silicon oxide film, and
in the removing the protective film, wet etching is performed using a solution containing hydrofluoric acid.

14. The method of manufacturing a light detection apparatus according to claim 12, wherein
the protective film is a metal film, and
in the removing the protective film, wet etching is performed using a solution containing sulfuric acid.
